(19) United States
(12) Patent Application Publication
(10) Pub. No.: US 2012/0229992 A1
(43) Pub. Date: Sep. 13, 2012

(54) MULTILAYERED COMPOSITE SYSTEMS, PRODUCTION THEREOF AND USE THEREOF

(75) Inventors: Leonhard Eichner, Ludwigshafen (DE); Bernd Dettling, Achern (DE); Andrea Dettling (Heir), Achern (DE)

(73) Assignee: BASF SE, Ludwigshafen (DE)

(21) Appl. No.: 13/411,875

(22) Filed: Mar. 5, 2012

Related U.S. Application Data
(60) Provisional application No. 61/449,737, filed on Mar. 7, 2011.

(51) Int. Cl. H05K 1/18; B32B 38/00; B32B 37/12; B32B 3/24

(52) U.S. Cl. 361/748; 428/138; 156/245; 156/182

(57) ABSTRACT

Multilayered composite system comprising
(A) a sheetlike substrate,
(B) optionally a bonding layer, which may be formed uniformly or partially,
(C) a foam layer,
(D) optionally a bonding layer of the same material as said bonding layer (B) or of a material other than said bonding layer (B),
(E) a polymer layer which includes capillaries extending through the entire thickness of said polymer layer (E),
   wherein said polymer layer (E) includes a pattern with a fishscale or sharkskin appearance.

The present invention relates to multilayered composite systems comprising
(A) a sheetlike substrate,
(B) optionally a bonding layer, which may be formed uniformly or partially,
(C) a foam layer,
(D) optionally a bonding layer which is the same as or different from said bonding layer (B), optionally a bonding layer of the same material as said bonding layer (B) or of a material other than said bonding layer (B),
(E) a polymer layer which includes capillaries extending through the entire thickness of said polymer layer (E),
   wherein said polymer layer (E) includes a pattern with a fishscale or sharkskin appearance.

The present invention further relates to a process for producing multilayered composite systems. The present invention further relates to the use of multilayered composite systems that are in accordance with the present invention.

Equipping watercraft and at least partially water-covered facilities, for example built structures in water-containing surroundings, for example in harbors, to render them resistant to fouling is very important. Ships with fouling by algae, plants and animals, especially shells and acorn barnacles, have an appreciably higher fuel consumption than in the cleaned state. Numerous traditional methods of controlling fouling are known, but have disadvantages.

The ancients already tried to reduce fouling by shells, algae and acorn barnacles by attaching plates of lead below the waterline. One disadvantage with this is, however, the high specific density of lead, appreciably reducing the potential load-carrying capacity of the ships. Another disadvantage is the fact that soluble lead compounds are toxic to humans. Lead plates were replaced by sheets of copper in the 18th century. The disadvantage with this is, however, that even copper is not corrosion-free and cannot be used to protect ships with steel hulls owing to the possible formation of local elements.

Especially ships with metal hulls have therefore often been protected with biocides based on tributyltin hydride (TBT). Owing to the toxicity and the risk of inducing hormonal disruptions in humans and animals, TBT-containing marine paints have since had to be taken off the market.

Silicone paints having a sharkskin texture have been reported. However, they have not therefore lead to a market-ready solution. It was apparently the hardness which was not satisfactory.

It is further known to paint ships' hulls with silicone-containing paints which produce a sharkskin pattern. However, painting ships, especially below the waterline, is very time-consuming and leads to long idle times for the ships in question.

The present invention has for its object to provide a method of protecting watercraft and at least partially water-covered facilities against undesired growth of algae, plants and/or animals. The present invention further has for its object to provide components whereby watercraft and at least partially water-covered facilities can be protected against undesired growth of algae, plants and/or animals without having to incur the disadvantages known in the prior art. The present invention further has for its object to provide watercraft and at least partially water-covered facilities that are protected against undesired growth of algae, plants and/or animals.

We have found that this object is achieved by the multilayered composite systems defined at the beginning, which in the context of the present invention are also referred to as inventive composite systems or inventive multilayered composite systems.

Inventive multilayered composite systems comprise
(A) a sheetlike substrate, also called sheetlike substrate (A) or layer (A),
(B) optionally a bonding layer, which may be formed uniformly or partially, also called bonding layer (B) or layer (B),
(C) a foam layer, also called foam layer (C) or layer (C),
(D) optionally a bonding layer, also called bonding layer (D) or layer (D), which is the same as or different from said bonding layer (B), optionally a bonding layer of the same material as said bonding layer (B) or of a material other than said bonding layer (B),
(E) a polymer layer which is also called polymer layer (E) or layer (E) and which includes capillaries extending through the entire thickness of said polymer layer (E),
   wherein said polymer layer (E) includes a pattern with a fishscale or sharkskin appearance.

The arrangement of layers (A) to (E) corresponds to the abovementioned order.

Inventive multilayered composite systems comprise a sheetlike substrate (A). Sheetlike substrates (A) in the context of the present invention are substrates whose extension in two dimensions is much greater than in the third dimension, for example the width and length of sheetlike substrate (A) can each exceed the thickness by a factor of at least 100 and preferably by a factor of at least 1000.

In one embodiment, the length and/or width of sheetlike substrate (A) exceed the thickness by a factor of up to 1 000 000.

The length and width of sheetlike substrate (A) may in each case be the same or preferably different. For example, the length of sheetlike substrate (A) may exceed the width by a factor in the range from 1.1 up to 100.

In one embodiment of the present invention, the length of sheetlike substrate (A) is in the range from 50 cm to 100 m, preferably up to 50 m and more preferably up to 10 m.

In one embodiment of the present invention, the width of sheetlike substrate (A) is in the range from 10 cm to 5 m and preferably up to 2 m.

In one embodiment of the present invention, the thickness of sheetlike substrate (A) is in the range from 50 nm to μm to 2 mm and preferably in the range from 100 μm up to 500 μm.

Sheetlike substrate (A) may consist of one or more materials. Sheetlike substrate (A) is preferably selected from wovens, nonwovens, polymeric foils, metallic foils and composite foils, especially metallized polymeric foils. Examples of preferred wovens or nonwovens are wovens or nonwovens of polyester and nonwovens of thermoplastic polyurethane (TPU). Examples of preferred polymeric foils are PVC foils, polyethylene foils, polypropylene foils, foils of polystyrene, polyamide or polyester, especially polyethylene terephthalate (PET). Examples of particularly preferred metallic foils are aluminum foils.

In one embodiment of the present invention, sheetlike substrate (A) is selected from metallized polymeric foils, for example foils of metallized polyethylene, metallized polypropylene, metallized polyester, especially metallized polyethylene terephthalate, and metallized polystyrene. Aluminum or iron is preferably chosen as metal for the metallization.

One other embodiment of the present invention comprises selecting sheetlike substrate from recyclate, for example from recycled plastic.

In one embodiment of the present invention, sheetlike substrate (A) has an E-modulus in the range from 200 to 5000 N/mm², determinable to DIN 53455 for example. Suitable are in particular sheetlike substrates having an E-modulus in the range from 200 to 1000 N/mm², which comprise predominantly polyethylene (HDPE or LDPE) for example, in the range from 1000 to 3500 N/mm², which comprise predominantly unplasticized PVC for example, or in the range from 4000 to 4500 N/mm², which comprise predominantly PET.

In one embodiment of the present invention, sheetlike substrate is selected from polymeric foils composed of additized plastic. Suitable additives may be selected for example from plasticizers, impact modifiers, stabilizers, colorants, fillers, reinforcing agents and waxes.

Inventive multilayered composite system may further include a bonding layer (B), which may be formed uniformly or partially.

Said bonding layer (B) may be for example an interrupted, i.e., nonuniformly incarnated, layer, preferably of a cured organic adhesive.

In one embodiment of the present invention, said bonding layer (B) is a layer applied pointwise, in strip form or in lattice form, for example in the form of diamonds, rectangles, squares or a honeycomb structure. In that case, foam layer (C) comes into contact with sheetlike substrate (A) in the gaps in bonding layer (B).

In one embodiment of the present invention, said bonding layer (B) is a layer of a cured organic adhesive, for example on the basis of polyvinyl acetate, polyacrylate or especially polyurethane, preferably on the basis of polyurethanes having a glass transition temperature below 0° C., for example determined by DSC (Differential Scanning calorimetry) to DIN 53765.

The cured organic adhesive may have been cured for example thermally, through actinic radiation or by aging.

In one other embodiment of the present invention, said bonding layer (B) is an adhesive gauze.

In one embodiment of the present invention, said bonding layer (B) has thickness in the range from one to not more than 100 μm, preferably to 50 μm and more preferably to 15 μm.

In one other embodiment of the present invention, inventive composite system comprises no bonding layer (B).

In one embodiment of the present invention, said bonding layer (B) as well as layers (C), (D) and (E) may optionally comprise one or more additives, for example one or more flame retardants and/or stabilizers such as antioxidants and/or light stabilizers.

Useful flame retardants include for example inorganic flame retardants, halogenated organic compounds, organophosphorus compounds or halogenated organophosphorus compounds.

Useful inorganic flame retardants include for example phosphates such as ammonium phosphates, aluminum hydroxides, aluminum oxide hydrates, zinc borates, antimony oxide.

Useful halogenated organic compounds include for example chloroparaffins, polychlorinated biphenyls, hexabromabenzene, polybrominated diphenyl ethers (PBDEs) and other bromine compounds, addition products of hexachlorocyclopentadiene, for example with cyclooctadiene, tetrabromobisphenol A, tetrabromophthalic anhydride, dibromoneopentylglycol.

Useful organophosphorus compounds include for example organic phosphates, phosphites and phosphonates, for example tricresyl phosphate and tert-butylphenyl diphenyl phosphate.

Useful halogenated organophosphorus compounds include for example tris(2,3-dibromopropyl)phosphate, tris(2-bromo-4-methylphenyl)phosphate and tris(2-chloroisopropyl)phosphate.

Preferred flame retardants include for example polyvinyl chlorides or polyvinylidene chlorides such as copolymers of vinylidene chloride with (meth)acrylic esters. Products of this type are marketed for example under the trade name of Diofan®.

Useful light stabilizers include for example free-radical scavengers such as sterically hindered organic amines (HALSs), peroxide decomposers such as for example benzotriazoles such as 2-(2-hydroxyphenyl)-2H-benzotriazoles (BTZs) or hydroxybenzophenones (BPs). Useful light stabilizers further include for example (2-hydroxyphenyl)-s-triazines (HPTs), oxalanilides or nonpigmentary titanium dioxide.

Useful light stabilizers are available for example under the trade name of Irganox®, Irgastab® or Tinuvin®.

HALS compounds are preferred light stabilizers.

Inventive composite systems further comprise a foam layer (C). Foam is defined in German standard specification DIN 7726 as referring to a material of construction which has cells distributed throughout its entire mass and an envelope density which is lower than the density of the scaffolding substance.

Foam (C) may be closed-cell, but in the context of the present invention is preferably mostly open-cell. In one embodiment of the present invention, 50% of all the lamellae are open, preferably 60 to 100% and more preferably 65 to 99.9%, determined to DIN ISO 4590. An open lamella (cell) is defined as a cell which is in communication with other cells via the gas phase.

In one embodiment of the present invention, the density of foam (C) is preferably between 5 to 1000 kg/m³, preferably in the range from 6 to 300 kg/m³ and more preferably in the range from 7 to 250 kg/m³.

In one embodiment of the present invention, foam (C) has a breaking extension above 100%.

In one embodiment of the present invention, foam (C) can have a (number) average diameter in the range from 1 μm to 1 mm and preferably in the range from 50 to 500 μm, determined by analyzing micrographs of sections.

Foam (C) may be of natural or synthetic origin. For example, foam (C) may be selected from natural sponges of the kind used as cleansing articles for example.

Examples of synthetic foams are polystyrene foams that are also known as expanded polystyrene, polyurethane foams, butadiene-styrene block copolymer foams, polyester foams and aminoplast foams. Foamed PVC materials, such as PVC plastisols, are also particularly suitable.

In one embodiment of the present invention, foam layer (C) may comprise from 20 to 80% of the thickness of inventive multilayered composite system, preferably in the range from 40 to 60% and more preferably in the range from 45 to 55%.

In one embodiment of the present invention, foam layer (C) is a layer of a foamed polyurethane adhesive. In the embodiments in which a layer of a foamed polyurethane adhesive is chosen as foam layer (C), inventive composite system preferably comprises no bonding layer (B).

Inventive composite systems may further comprise a bonding layer (D) which is of the same material as bonding layer (B) or is of a material other than bonding layer (B). Bonding layer (D) may be formed uniformly or partially.

Said bonding layer (D) may be for example an interrupted, i.e., nonuniformly incarnated, layer, preferably of a cured organic adhesive.

In one embodiment of the present invention, said bonding layer (D) is a layer applied pointwise, in strip form or in lattice form, for example in the form of diamonds, rectangles, squares or a honeycomb structure. In that case, foam layer (C) comes into contact with polymer layer (E) in the gaps in bonding layer (D).

In one embodiment of the present invention, said bonding layer (D) is a layer of a cured organic adhesive, for example on the basis of polyvinyl acetate, polyacrylate or especially polyurethane, preferably on the basis of polyurethanes having a glass transition temperature below 0° C., for example determined by DSC (Differential Scanning calorimetry) to DIN 53765.

The cured organic adhesive may have been cured for example thermally, through actinic radiation or by aging.

In one other embodiment of the present invention, said bonding layer (D) is an adhesive gauze.

In one embodiment of the present invention, said bonding layer (D) has thickness in the range from one to not more than 100 μm, preferably to 50 μm and more preferably to 15 μm.

In one embodiment of the present invention, bonding layer (B) and bonding layer (D) have the same incarnation, for example each as an adhesive gauze.

In one other embodiment of the present invention, bonding layer (B) and bonding layer (D) are based on the same material, but have a different incarnation, for example in that bonding layer (D) may be formed uniformly and bonding layer (B) partially, for example as a layer applied pointwise, in strip form or lattice form, for example in the form of diamonds, rectangles, squares or a honeycomb structure.

In embodiments in which a layer of a foamed polyurethane adhesive is chosen as foam layer (C), inventive composite system preferably comprises no bonding layer (D).

In embodiments in which a layer of a foamed polyurethane adhesive is chosen as foam layer (C), inventive composite system preferably comprises neither a bonding layer (B) nor a bonding layer (D).

Inventive composite system comprises a polymer layer (E) which includes capillaries extending throughout the entire thickness of polymer layer (E), i.e., polymer layer (E) includes through-capillaries.

All thermoplastic polymers capable of being provided in the form of preferably aqueous dispersions are suitable. They preferably have a glass transition temperature less than 0° C., determined for example by DSC (Differential Scanning calorimetry) according to DIN 53765.

Polymer layer (E) may consist essentially of the following polymers for example: polyacrylate, epoxy resin, polyvinyl acetate, polyvinyl chloride, polyvinylidene chloride, polyacrylonitrile, polystyrene, polybutadienes, polyurethane or mixtures thereof.

Suitable polymers include for example polyacrylates, epoxy resins, polyvinyl acetates, polyvinyl chlorides, polyvinylidene chloride, polystyrenes, polybutadienes, polyurethanes or mixtures thereof.

Polystyrene in the context of the present invention is to be understood as meaning inter alia all homo- or copolymers formed by polymerization of styrene and/or derivatives of styrene. Derivatives of styrene include for example alkylstyrenes such as alpha-methylstyrene, ortho-methylstyrene, meta-methylstyrene, para-methylstyrene, para-butylstyrene especially para-tert-butylstyrene, alkoxystyrene such as para-methoxystyrene, para-butoxystyrene, para-tert-butoxystyrene.

The average molar mass Mₙ of suitable polystyrenes is generally in the range from 5000 to 1 000 000 g/mol (determined by GPC), preferably in the range from 20 000 to 750 000 g/mol and more preferably in the range from 30 000 to 500 000 g/mol.

In one preferred embodiment, the matrix of the color converter consists essentially or completely of a homopolymer of styrene or styrene derivatives.

In further preferred embodiments of the invention, the matrix consists essentially or completely of a styrene copolymer which, for the purposes of this invention, is likewise regarded as a polystyrene. Styrene copolymers may comprise for example, as further constituents, butadiene, acrylonitrile, maleic anhydride, vinylcarbazole or esters of acrylic, methacrylic or itaconic acid as monomers. Suitable styrene copolymers generally comprise at least 20 wt % of styrene preferably at least 40 and more preferably at least 60 wt % of styrene. In another embodiment, they comprise at least 90 wt % of styrene. Preferred styrene copolymers are styrene-acrylonitrile copolymers (SAN) and acrylonitrile-butadiene-styrene copolymers (ABS), styrene-1,1′-diphenyl-ethene copolymers, acrylic ester-styrene-acrylonitrile copolymers (ASA), styrene-butadiene copolymers (such as SB dispersions), methyl methacrylate-acrylonitrile-butadiene-styrene copolymers (MABS).

A further preferred polymer is alpha-methylstyrene-acrylonitrile copolymer (AMSAN).

Styrene homo- or copolymers are obtainable for example by free-radical polymerization, cationic polymerization, anionic polymerization or under the influence of organometallic catalysts (Ziegler-Natta catalysis for example). This can lead to isotactic, syndiotactic, atactic polystyrene/copolymers. They are preferably prepared by free-radical polymerization. The polymerization can be carried out as suspension polymerization, emulsion polymerization, solution polymerization or bulk polymerization.

Suitable polyacrylates generally have a molecular weight of 5000 to 1 000 000 g/mol. Suitable polyacrylates are preferably obtainable by free-radical (co)polymerization of appropriate comonomers, preferably by free-radical emulsion copolymerization which, in the context of the present invention, is also simply referred to as free-radical emulsion polymerization. Polyacrylate dispersions are also obtainable via solution copolymerization. The latter is known from U.S. Pat. No. 5,221,284, U.S. Pat. No. 5,376,459 for example.

Particular preference is given to polyacrylates obtainable selected from at least one of the following monomers via free-radical copolymerization:
1) acrylic acid and methacrylic acid and their derivatives of the formula CH₂═CR¹—CO—OR², where R¹ is hydrogen or methyl and R² is a hydrocarbon moiety of 1 to 40 carbon atoms which may also be substituted by fluorine, hydroxyl, C₁₋₄alkylamino, C₁₋₄alkoxy, carbonyl groups and also polyether groups, preferably with R² having 1 to 10 carbon atoms and more preferably with R² being methyl, ethyl, propyl, isopropyl, butyl, tert-butyl, hexyl, ethylhexyl;
2) acrylamide, methyacrylamide and derivatives thereof,
3) styrene and substituted styrenes such as alpha-methylstyrene,
4) acrylonitrile,
5) vinyl esters such as vinyl acetate, vinyl propionate and/or
6) unsaturated dicarboxylic acids such as crotonic acid, haconic acid or maleic anhydride.
   Suitable binders also include mixtures of polyacrylate and polyurethane dispersions or dispersions obtained by grafting acrylate comonomers onto polyurethane dispersions (PUR-PAC hybrids), with the proviso that they have a Shore A hardness appropriate for production of primers and optionally are self-crosslinking or crosslinkable with customary crosslinkers.
7) olefins such as ethylene.

In one preferred embodiment, suitable polyacrylates comprise no copolymerized comonomers capable of detaching formaldehyde on exposure to temperatures in the range from 100 to 250° C., such as N-methylol(meth)acrylamide for example.

In another embodiment, suitable polyacrylates do comprise copolymerized comonomers capable of detaching formaldehyde on exposure to temperatures in the range from 100 to 250° C., such as N-methylol(meth)acrylamide for example.

Suitable polyacrylates are preferably obtained by free-radical copolymerization of at least two comonomers of which at least one is selected from (meth)acrylic acid and (meth)acrylates, for example C₁-C₂₀-alkyl(meth)acrylates and preferably C₁-C₁₀-alkyl(meth)acrylates, and which preferably account for at least 50 wt % of binder (A).

In one embodiment of the present invention, suitable polyacrylates are selected from copolymers comprising as copolymerized comonomer (meth)acrylic acid, comonomer having an epoxy group in the molecule such as for example glycidyl(meth)acrylate, ω-C₂-C₁₀-hydroxyalkyl (meth)acrylate or (meth)acrylic esters of alcohols of the general formula I

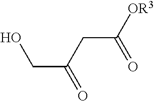

where
R³ is selected from branched and preferably unbranched C₁-C₁₀-alkyl, such as methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl, n-heptyl, n-octyl, 2-ethylhexyl, n-nonyl, n-decyl, more preferably unbranched C₁-C₄-alkyl such as methyl, ethyl, n-propyl and n-butyl.

Useful poly(meth)acrylates for the purposes of the present invention further include copolymers of one or more C₁-C₁₀-alkyl esters of (meth)acrylic acid, which may comprise for example (meth)acrylic acid, glycidyl(meth)acrylate or C₂-C₁₀-hydroxyalkyl(meth)acrylate and optionally one or more further comonomers in copolymerized form. Useful further monomers include for example vinylaromatics such as α-methylstyrene, para-methylstyrene and especially styrene, also (meth)acrylamide, vinyl chloride, (meth)acrylonitrile.

Examples of particularly suitable C₁-C₁₀-alkyl esters of (meth)acrylic acid are methyl (meth)acrylate, ethyl(meth)acrylate, n-propyl(meth)acrylate, isopropyl(meth)acrylate, n-butyl(meth)acrylate, n-hexyl(meth)acrylate, 2-ethylhexyl(meth)acrylate, n-decyl (meth)acrylate.

Examples of particularly suitable ω-hydroxy-C₂-C₁₀-alkylene esters of (meth)acrylic acid are especially ω-hydroxy-C₂-C₁₀-(meth)acrylates such as 6-hydroxyhexyl(meth)acrylate, 4-hydroxybutyl(meth)acrylate, 3-hydroxypropyl(meth)acrylate and especially 2-hydroxyethyl (meth)acrylate.

One preferred version comprises selecting suitable polyacrylates from such poly(meth)acrylates as comprise copolymers of one or more C₁-C₁₀-alkyl esters or (meth)acrylic acid and (meth)acrylic acid and at least one comonomer selected from glycidyl(meth)acrylate and C₂-C₁₀-hydroxyalkyl(meth)acrylate in copolymerized form, plus optionally one or more further comonomers.

When polyacrylates comprising (meth)acrylic acid in copolymerized form are used, the carboxyl groups of the copolymerized (meth)acrylic acid can be present in free form or in completely or partially neutralized form, for example completely or partially neutralized with alkali, with ammonia or with amine. Particularly suitable amines include for example tertiary amines, e.g., (C₁-C₄-alkyl)₃N, especially triethylamine, and alkanolamines such as for example ethanolamine, diethanolamin, triethanolamine, N-methylethanolamine, N,N-dimethylethanolamine and N-(n-butyl)ethanolamine.

Suitable polybutadienes are generally copolymers of butadiene with acrylonitrile and/or styrene and/or (meth)acrylic esters and/or optionally other unsaturated monomers. Suitable polybutadienes dispersions can be crosslinked with metal oxides such as zinc oxide on application.

Suitable polyvinylidene chlorides are generally copolymers of vinylidene chloride with (meth)acrylic esters. Products of this type are marketed for example under the trade name of Diofan®.

Suitable polyvinyl chlorides (PVC) are preferably obtained by homopolymerization of vinyl chloride. In another embodiment, suitable polyvinyl chlorides are obtained by copolymerization of vinyl chloride with other comonomers.

Suitable polyvinyl chlorides are obtainable for example by emulsion polymerization or suspension polymerization.

Suitable polyvinyl chloride dispersions are commercially available for example under the trade names of SolVin® or Diofan®.

Epoxy resins are prepared either by catalytic polymerization of epoxides (oxiranes) or by reaction of epoxides, for example epichlorohydrin with diols, for example with bisphenols such as bisphenol A or bisphenol F.

Suitable epoxy resins can be for example liquid or solid resins based on bisphenol A or F. Suitable liquid epoxy resins, such as bisphenol A diglycidyl ethers, typically have a molecular weight of 200 to 1000 g/mol, preferably of 300 to 500 g/mol and more preferably of about 380 g/mol. Suitable epoxy resins are frequently bifunctional. A molar mass of 380 g/mol then corresponds to an epoxy equivalent weight (EEW) of 190 g/mol. No further additives are needed to use the inexpensive, water-insoluble, liquid resins in aqueous systems. In these cases, the hardener used acts as an emulsifier.

Suitable hydrophobic solid resins frequently have a molecular weight of 500 to 5000 g/mol, preferably of 700 to 3000 g/mol, more preferably of 900 to 2000 g/mol and more preferably of 1000 to 1500 g/mol. In untreated form they are not compatible with waterborne systems. Dispersions of such resins are obtainable by using reactive nonionic emulsifiers. Stable emulsions generally have an average particle diameter of less than one micrometer.

The less preferable solventborne 2-part epoxy resins based on bisphenol A diglycidyl ethers can be hardened with amines and amine derivatives or mercaptans for example. The amine hardeners used for this purpose can be for example cycloaliphatic low molecular weight amines such as meta-xylenediamine (MXDA), isophoronediamine (IPDA), diethylenetriamine (DETA), triethylenetetraamine (TETA), polymeric polyaminoamides or water-soluble emulsifying amine-containing polymers.

Suitable aqueous 2-part epoxy resin systems are obtainable for example by emulsifying liquid epoxy resins with suitable surface-active compounds and modifying hardeners such as polyamidoamine hardeners for example through addition of emulsifiers and protonation to the effect that they became water-soluble.

Aqueous hardeners may consist at the molecular level of a balanced ratio of hydrophobic and hydrophilic elements which permit self-emulsification on the part of liquid resins. The above-mentioned amines can be used for this as a reactant and later crosslinking site because their structure tends to be either hydrophilic (TETA for example) or hydrophobic (IPDA for example). Typical hydrophilic elements of a hardener structure are for example nonionic polyethylene-polypropylene glycol elements of differing molecular weight, while bisphenol A diglycidyl ether compounds are frequently used as hydrophobic component. Hardeners having a variety of properties are obtainable by carefully constructing the molecular structure from these or similar building blocks. Typical self-emulsifying epoxy hardeners are available from BASF under the trade names of WEX, Waterpoxy® for example.

Among aqueous epoxy resin systems there are especially two different types which are suitable, which are known as type I and type II systems. Type I systems are based on liquid resin systems of EEW<250. Type II systems are based on solid resin emulsions of EEW>250.

In type I systems, the hardener used acts not only as hardener but also as emulsifier for the liquid resin. This means that the emulsion particles in such systems comprise not only resin but also hardener very quickly after the mixing of resin and hardener. In addition, a certain proportion of the hardener can also be present in the aqueous phase. The spatial closeness of resin and hardener within the same emulsion particle frequently leads to rapid curing with correspondingly short pot life (<3 h). One advantage of type I systems is that they can often be formulated to be completely VOC-free. Owing to the short spacings of the crosslink points and the rigid polymer backbone, the cured films combine high hardness with an often low flexibility and high chemical resistance.

Type II systems are typically based on solid resin emulsions of EEW>250 and a solids content of 45-62%. Since the solid resin is already in the form of an emulsion, the use of self-emulsifying hardeners as in type I systems is not absolutely necessary, although it is still perfectly possible. Accordingly, a distinctly wider range of useful hardeners is available for type II systems. For example, non-self-emulsifying hardeners such as amine-based hardeners such as Waterpoxy® 801 can be used, but also self-emulsifying hardeners such as Waterpoxy® 751 for example.

Unlike type I systems, the emulsified higher molecular weight solid resins of the type II systems need coalescers in order that good filming may be ensured. Accordingly, unlike type I systems, they usually have a VOC content of 50-150 g/l. It is likewise possible to use VOC-free solid resin emulsions.

Polyurethanes (PUs) are common general knowledge, commercially available and consist in general of a soft phase of comparatively high molecular weight polyhydroxy compounds, for example of polycarbonate, polyester or polyether segments, and a urethane hard phase formed from low molecular weight chain extenders and di- or polyisocyanates.

Processes for preparing polyurethanes (PUs) are common general knowledge. In general, polyurethanes (PUs) are prepared by reaction of
(i) isocyanates, preferably diisocyanates, with
(ii) isocyanate-reactive compounds, typically having a molecular weight (Mw) in the range from 500 to 10 000 g/mol, preferably in the range from 500 to 5000 g/mol and more preferably in the range from 800 to 3000 g/mol, and
(iii) chain extenders having a molecular weight in the range from 50 to 499 g/mol, optionally in the presence of
(iv) catalysts
(v) and/or customary additive materials.

In what follows, the starting components and processes for preparing the preferred polyurethanes (PUs) will be described by way of example. The components (i), (ii), (iii) and also optionally (iv) and/or (v) customarily used in the preparation of polyurethanes (PUs) will now be described by way of example:

As isocyanates (i) there may be used commonly known aliphatic, cycloaliphatic, araliphatic and/or aromatic isocyanates, examples being tri-, tetra-, penta-, hexa-, hepta- and/or octamethylene diisocyanate, 2-methylpentamethylene 1,5-diisocyanate, 2-ethylbutylene 1,4-diisocyanate, pentamethylene 1,5-diisocyanate, butylene 1,4-diisocyanate, 1-isocyanato-3,3,5-trimethyl-5-isocyanatomethylcyclohexane (isophorone diisocyanate, IPDI), 1,4- and/or 1,3-bis(isocyanatomethyl)cyclohexane (HXDI), 1,4-cyclohexane diisocyanate, 1-methyl-2,4- and/or -2,6-cyclohexane diisocyanate and/or 4,4′-, 2,4′- and 2,2′-dicyclohexylmethane diisocyanate, 2,2′-, 2,4′- and/or 4,4′-diphenylmethane diisocyanate (MDI), 1,5-naphthylene diisocyanate (NDI), 2,4- and/or 2,6-toluoylene diisocyanate (TDI), diphenylmethane diisocyanate, 3,3′-dimethyldiphenyl diisocyanate, 1,2-diphenylethane diisocyanate and/or phenylene diisocyanate. Preference is given to using 4,4′-MDI. Preference is also given to aliphatic diisocyanates, especially hexamethylene diisocyanate (HDI), and particular preference is given to aromatic diisocyanates such as 2,2′-, 2,4′- and/or 4,4′-diphenylmethane diisocyanate (MDI) and mixtures of the aforementioned isomers.

As isocyanate-reactive compounds (ii) there may be used the commonly known isocyanate-reactive compounds, examples being polyesterols, polyetherols, and/or polycarbonate diols, which are customarily also subsumed under the term “polyols”, with molecular weights (M_{w}) in the range from 500 to 8000 g/mol, preferably in the range from 600 to 6000 g/mol and especially in the range from 800 to 3000 g/mol, and preferably with an average functionality toward isocyanates in the range from 1.8 to 2.3, preferably in the range from 1.9 to 2.2 and especially 2. Preference is given to using polyether polyols, for example those based on commonly known starter substances and customary alkylene oxides, for example ethylene oxide, 1,2-propylene oxide and/or 1,2-butylene oxide, preferably polyetherols based on polyoxytetramethylene (polyTHF), 1,2-propylene oxide and ethylene oxide. Polyetherols have the advantage of having a higher hydrolysis stability than polyesterols, and are preferably used as component (ii), especially for preparing soft polyurethanes polyurethane (PU1).

As polycarbonate diols there may be mentioned in particular aliphatic polycarbonate diols, for example 1,4-butanediol polycarbonate and 1,6-hexanediol polycarbonate.

As polyester diols there are to be mentioned those obtainable by polycondensation of at least one primary diol, preferably at least one primary aliphatic diol, for example ethylene glycol, 1,4-butanediol, 1,6-hexanediol, neopentylglycol or more preferably 1,4-dihydroxymethylcyclohexane (as isomer mixture) or mixtures of at least two of the aforementioned diols on the one hand and at least one, preferably at least two dicarboxylic acids or their anhydrides on the other.

Preferred dicarboxylic acids are aliphatic dicarboxylic acids such as adipic acid, glutaric acid, succinic acid and aromatic dicarboxylic acids such as, for example, phthalic acid and especially isophthalic acid.

Polyetherols are preferably prepared by addition of alkylene oxides, especially ethylene oxide, propylene oxide and mixtures thereof, on to diols such as, for example, ethylene glycol, 1,2-propylene glycol, 1,2-butylene glycol, 1,4-butanediol, 1,3-propanediol, or on to triols such as, for example, glycerol, in the presence of high-activity catalysts. High-activity catalysts of this type are for example cesium hydroxide and dimetal cyanide catalysts, also known as DMC catalysts. Zinc hexacyanocobaltate is a frequently employed DMC catalyst. The DMC catalyst can be left in the polyetherol after the reaction, but preferably it is removed, for example by sedimentation or filtration.

Mixtures of various polyols can be used instead of just one polyol.

To improve dispersibility, isocyanate-reactive compounds (ii) may also include a proportion of one or more diols or diamines having a carboxylic acid group or sulfonic acid group (b′), especially alkali metal or ammonium salts of 1,1-dimethylolbutanoic acid, 1,1-dimethylolpropionic acid or

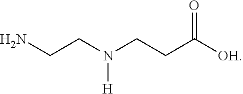

Useful chain extenders (iii) include commonly known aliphatic, araliphatic, aromatic and/or cycloaliphatic compounds having a molecular weight in the range from 50 to 499 g/mol and at least two functional groups, preferably compounds having exactly two functional groups per molecule, examples being diamines and/or alkanediols having 2 to 10 carbon atoms in the alkylene moiety, especially 1,3-propanediol, 1,4-butanediol, 1,6-hexanediol and/or di-, tri-, tetra-, penta-, hexa-, hepta-, octa-, nona- and/or decaalkylene glycols having 3 to 8 carbon atoms per molecule, preferably the corresponding oligo- and/or polypropylene glycols, and mixtures of chain extenders (iii) can also be used.

It is particularly preferable for components (i) to (iii) to be difunctional compounds, i.e., diisocyanates (i), difunctional polyols, preferably polyetherols (ii) and difunctional chain extenders, preferably diols.

Useful catalysts (iv), which speed especially the reaction between the NCO groups of the diisocyanates (i) and the hydroxyl groups of components (ii) and (iii), are customary tertiary amines, for example triethylamine, dimethylcyclohexylamine, N-methylmorpholine, N,N′-dimethylpiperazine, 2-(dimethylaminoethoxy)ethanol, diazabicyclo(2,2,2)octane (DABCO) and similar tertiary amines, and also especially organic metal compounds such as titanic esters, iron compounds such as, for example, iron(III) acetylacetonate, tin compounds, for example tin diacetate, tin dioctoate, tin dilaurate or the tin dialkyl salts of aliphatic carboxylic acids such as dibutyltin diacetate, dibutyltin dilaurate or the like. The catalysts are typically used in amounts of 0.0001 to 0.1 part by weight per 100 parts by weight of component (ii).

Auxiliaries and/or additives (v) can be added to the components (i) to (iii) as well as catalyst (iv). There may be mentioned for example blowing agents, antiblocking agents, surface-active substances, fillers, for example fillers based on nanoparticles, especially fillers based on CaCO₃, nucleators, glidants, dyes and pigments, antioxidants, for example against hydrolysis, light, heat or discoloration, organic and/or inorganic fillers, reinforcing agents and plasticizers, metal deactivators. In one preferred embodiment, component (v) also includes hydrolysis stabilizers such as, for example polymeric and low molecular weight carbodiimides. The soft polyurethane preferably comprises triazole and/or triazole derivative and antioxidants in an amount of 0.1 to 5 wt % based on the total weight of the soft polyurethane in question. Useful antioxidants are generally substances that inhibit or prevent unwanted oxidative processes in the plastics material to be protected. In general, antioxidants are commercially available. Examples of antioxidants are sterically hindered phenols, aromatic amines, thiosynergists, organophosphorous compounds of trivalent phosphorous and hindered amine light stabilizers. Examples of sterically hindered phenols appear in the Plastics Additive Handbook, 5th edition, H. Zweifel, ed, Hanser Publishers, Munich, 2001 ([1]), pp. 98-107 and p. 116-p. 121. Examples of aromatic amines appear in [1] pp. 107-108. Examples of thiosynergists are given in [1], pp. 104-105 and pp. 112-113. Examples of phosphites are given in [1], pp. 109-112. Examples of hindered amine light stabilizers are given in [1], pp. 123-136. Phenolic antioxidants are preferable for use in the antioxidant mixture. In one preferred embodiment, the antioxidants, especially phenolic antioxidants, have a molar mass of above 350 g/mol and more preferably of above 700 g/mol and a maximum molar mass (M_{w}) of not more than 10 000 g/mol and preferably up to not more than 3000 g/mol. They further preferably have a melting point of not more than 180° C. It is further preferable to use antioxidants that are amorphous or liquid. Mixtures of two or more antioxidants can likewise be used as component (v).

As well as the recited components (i), (ii) and (iii) and optionally (iv) and (v), chain transfer agents (chain-terminating agents), customarily having a molecular weight of 31 to 3000 g/mol, can also be used. Such chain transfer agents are compounds which have only one isocyanate-reactive functional group, examples being monofunctional alcohols, monofunctional amines and/or monofunctional polyols. Such chain transfer agents make it possible to adjust flow behavior, especially in the case of soft polyurethanes, to specific values. Chain transfer agents can generally be used in an amount of 0 to 5 parts and preferably 0.1 to 1 part by weight, based on 100 parts by weight of component (ii), and by definition come within component (iii).

As well as the recited components (i), (ii) and (iii) and optionally (iv) and (v), it is also possible to use crosslinkers having two or more isocyanate-reactive groups at the end of the polyurethane-forming reaction, for example hydrazine hydrate.

To adjust the hardness of polyurethane (PU), the components (ii) and (iii) can be chosen within relatively wide molar ratios. Useful are molar ratios of component (ii) to total chain extenders (iii) to be used in the range from 10:1 to 1:10 and especially in the range from 1:1 to 1:4, the hardness of soft polyurethanes increasing with increasing (iii) content. The reaction to produce polyurethane (PU) can be carried out at an index in the range from 0.8 to 1.4:1, preferably in the range from 0.9 to 1.2:1 and more preferably at an index in the range from 1.05 to 1.2:1. The index is defined by the ratio of all the isocyanate groups of component (i) used in the reaction to the isocyanate-reactive groups, i.e., the active hydrogens, of components (ii) and optionally (iii) and optionally monofunctional isocyanate-reactive components as chain-terminating agents such as monoalcohols for example.

Polyurethane (PU) can be prepared by conventional processes in a continuous manner, for example by the one-shot or the prepolymer process, or batchwise by the conventional prepolymer operation. In these processes, the reactant components (i), (ii), (iii) and optionally (iv) and/or (v) can be mixed in succession or simultaneously, and the reaction ensues immediately.

Polyurethane (PU) can be dispersed in water in a conventional manner, for example by dissolving polyurethane (PU) in acetone or preparing it as a solution in acetone, and admixing the solution with water and then removing the acetone, for example distillatively. In one version, polyurethane (PU) is prepared as a solution in N-methylpyrrolidone or N-ethylpyrrolidone, admixed with water and the N-methylpyrrolidone or N-ethylpyrrolidone is removed.

In one embodiment of the present invention, aqueous dispersions of the present invention comprise two different polyurethanes polyurethane (PU1) and polyurethane (PU2), of which polyurethane (PU1) is a so-called soft polyurethane which is constructed as described above for polyurethane (PU), and at least one hard polyurethane (PU2).

Hard polyurethane (PU2) can in principle be prepared similarly to soft polyurethane (PU1), but other isocyanate-reactive compounds (ii) or other mixtures of isocyanate-reactive compounds (ii), herein also referred to as isocyanate-reactive compounds (ii-2) or in short compound (ii-2), are used.

Examples of compounds (ii-2) are in particular 1,4-butanediol, 1,6-hexanediol and neopentylglycol, either mixed with each other or mixed with polyethylene glycol.

In one version of the present invention, diisocyanate (i) and polyurethane (PU2) are each mixtures of diisocyanates, for example mixtures of HDI and IPDI, larger proportions of IPDI being chosen for the preparation of hard polyurethane (PU2) than for the preparation of soft polyurethane (PU1).

In one embodiment of the present invention, polyurethane (PU2) has a Shore A hardness in the range from above 60 to not more than 100, the Shore A hardness being determined in accordance with German standard specification DIN 53505 after 3 s.

In one embodiment of the present invention, polyurethane (PU) has an average particle diameter in the range from 100 to 300 nm and preferably in the range from 120 to 150 nm, determined by laser light scattering.

In one embodiment of the present invention, soft polyurethane (PU1) has an average particle diameter in the range from 100 to 300 nm and preferably in the range from 120 to 150 nm, determined by laser light scattering.

In one embodiment of the present invention, polyurethane (PU2) has an average particle diameter in the range from 100 to 300 nm and preferably in the range from 120 to 150 nm, determined by laser light scattering.

Preferably, polymer layer (E) is a polyurethane layer, a PVC layer, a layer of an epoxy resin, a polyacrylate layer or a polybutadienes layer.

In one embodiment of the present invention, polymer layer (E) has an average thickness in the range from 15 to 300 μm, preferably in the range from 20 to 150 μm and more preferably in the range from 25 to 80 μm.

In one embodiment of the present invention, polymer layer (E) has on average at least 100 and preferably at least 250 capillaries per 100 cm².

In one embodiment of the present invention, the capillaries have an average diameter in the range from 0.005 to 0.05 mm and preferably in the range from 0.009 to 0.03 mm.

In one embodiment of the present invention, the capillaries are evenly distributed over polymer layer (E). In one preferable embodiment of the present invention, however, the distribution of the capillaries over the polymer layer (E) is uneven.

In one embodiment of the present invention, the capillaries are essentially arcuate. In one other embodiment of the present invention, the capillaries have an essentially straight-line course.

The capillaries endow the polymer layer (E) with a permeability to air and water vapor without any need for aperturing. In one embodiment of the present invention, the water vapor permeability of the polymer layer (E) is above 1.5 mg/cm²·h, measured to DIN 53333. It is thus possible for liquids comprising active material to migrate through the polymer layer (E) for example.

In one embodiment of the present invention, polymer layer (E) as well as capillaries has pores which do not extend through the entire thickness of the polymer layer (E).

Polymer layer (E) exhibits a pattern which has a fishscale or preferably sharkskin appearance. The length of fishscales therein can be in the range from 100 μm to 1 mm. Fishscale width can be in the range from 150 to 500 μm and preferably in the range from 250 to 350 μm. Fishscales preferably have no grooves. In another embodiment the polymer layer (E) exhibits a pattern with grooves.

In one preferable embodiment of the present invention, polymer layer (E) has a pattern which resembles sharkskin, specifically with teethlike scales having a length in the range from 100 μm to 1 mm and a width in the range from 150 to 500 μm, preferably in the range from 250 to 350 μm, and small grooves, so-called riblets, having a depth in the range from 20 to 100 μm, preferably in the range from 50 to 70 μm and a length in the range from 10 μm to 1 mm. The fishscale patterning may preferably create a sharkskin effect when inventive composite system moves through water.

In one embodiment of the present invention, one or more of layers (B) to (E) may comprise one or more biocides. Biocides may be selected for example from fungicides, algicides, molluscicides and antifouling products. Antifouling products are biocides that are active against shells and/or barnacles. Examples of barnacles are more particularly goose barnacles and acorn barnacles.

An example of particularly preferable biocides is diuron (3-(3,4-dichlorophenyl)-1,1-dimethylurea), a urea derivative of the formula

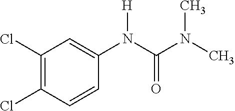

A further example of particularly preferable biocides is 4,5-dichloro-2-n-octyl-4-isothiazolin-3-one, an isothiazoline of the formula

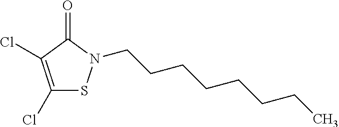

Further examples of particularly preferable biocides are copper and zinc salts of 2-pyridinethiol N-oxide, i.e., salts of the formula

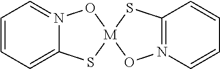

where M is selected from Cu and Zn.

A further example of particularly preferable biocides is cybutryn (trade name Irgarol®, 2-methylthio-4-tert-butylamino-6-cyclopropylamino-s-triazine), a triazine derivative of the formula

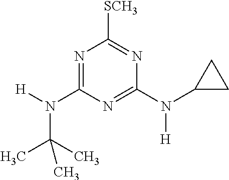

Further suitable biocides are selected from epoxiconazole, dithianon, 1,2-benzisothiazolin-3-one, 4,5-dichloro-2-n-octyl-3(2H)-isothiazolinone and Vanquish® 100 (N-butyl-1,2-benzisothiazolin-3-one, BBIT).

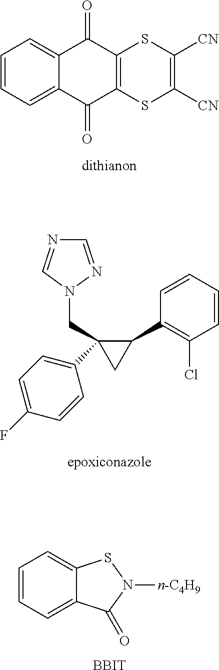

Methods of synthesizing the aforementioned biocides are known per se.

In one embodiment of the present invention, one or more of layers (B) to (E) comprise one or more biocides as such.

In one embodiment of the present invention, one or more of layers (B) to (E) comprise altogether from 0.1 to 10 wt % of one or more biocides, based on the weight of respectively bonding layer (B) or (D) or foam layer (C).

In one embodiment of the present invention, one or more of layers (B) to (E) comprise one or more biocides in encapsulated form. Encapsulation can be for example in polyurea-polyurethane, in melamine resin or in polyacrylate.

In one embodiment of the present invention, inventive composite system may additionally include one or more electroconnectivity-conferring elements, for example on sheetlike substrate (A), on foam layer (C) and preferably on that side of polymer layer (E) which faces away from foam layer (C). Examples of electroconnectivity-conferring elements are for example printed electric circuits, metallic laminations, metallic threads and metallizations. Metallization is to be understood as referring to a coating of metal from 100 to 1000 Å and preferably from 200 to 500 Å in thickness and at least 10 cm in width, more particularly a uniform coating. Metallic lamination refers to a metallic foil which has been applied to inventive multilayer composite system and is from 4 to 50 μm and preferably from 7 to 20 μm in thickness. Metallic threads are preferably one-dimensional metallic constructs having a diameter of 0.15 to 5.0 mm and preferably of 0.25 to 1.5 mm.

Inventive composite systems are for example very useful for equipping watercraft and at least partially water-covered facilities, more particularly those parts of watercraft or facilities that are below the waterline. Equipping may take the form of being applied by adhering for example. When adhesives that cure underwater are used, no dry dock is needed to work on watercraft. The present invention accordingly further provides for the use of inventive composite systems for equipping watercraft and at least partially water-covered facilities. The present invention further provides watercraft and at least partially water-covered facilities equipped with at least one inventive composite system.

Examples of at least partially water-covered facilities, generally also referred to as facilities for short, are port installations, for example dolphins, moles, quays, also pontoons, groins, dike bases, levees, bridges, buoys and drilling rigs.

Examples of watercraft are ships, boats, especially submarines, also canoes and rafts.

Preferably, only those surfaces of watercraft/facilities will have been equipped with the inventive composite systems that are temporarily covered by sea or river water. A ship's deck is thus preferably not equipped with inventive composite system.

Equipping can be effected by laminating or preferably by adhering in place, specifically by sheetlike substrate (A) facing the watercraft/facility and polymer layer (E) the water. In one version, watercraft are equipped by painting them with paint and applying inventive composite system atop the uncured or incompletely cured paint.

Watercraft and facilities equipped with inventive composite system are very resistant to fouling, even slow-moving watercraft.

The present invention further provides processes for producing inventive composite systems, also referred to as inventive production processes for short.

In one version, the inventive production process comprises a process which includes the following steps:
(a) using a mold to form a polymer layer (E),
(b) applying at least one organic adhesive uniformly or partially to foam layer (C) and/or to polymer layer (E) and then bonding polymer layer (E) to foam layer (C) pointwise, stripwise or areawise,
(c) optionally bonding the resulting composite body to sheetlike substrate (A) using an organic adhesive.

In one version, the inventive production process comprises a process which includes the following steps:
(a) using a mold to form a polymer layer (E),
(b′) applying at least one organic adhesive uniformly or partially to foam layer (C) and/or to sheetlike substrate (A) and then bonding sheetlike substrate (A) to foam layer (C) pointwise, stripwise or areawise,
(c′) optionally bonding the resulting composite body to polymer layer (E) using an organic adhesive.

In one other version of the inventive production process, one possible procedure includes the following steps:
(a) using a mold to form a polymer layer (E),
(b″) applying at least one organic adhesive based on a foamable polyurethane in a uniform, pointwise or stripwise manner to polymer layer (E) and/or to a sheetlike substrate (A),
(c″) mutually contacting polymer layer (E) and sheetlike substrate (A) such that the layer of adhesive based on foamable polyurethane comes to be positioned between said polymer layer (E) and said sheetlike substrate (A), and
(d″) foaming the adhesive based on foamable polyurethane to form the foam layer (C).

The mold is preferably a silicone mold. Silicone molds herein are molds prepared using at least one binder having at least one and preferably at least three O—Si(R¹R²)—O— groups per molecule, where R¹ and—if present—R² are different or preferably the same and are each selected from organic groups and preferably C₁-C₆-alkyl, especially methyl.

In one embodiment of the present invention, the silicone mold is a silicone mold structured by laser engraving.

Step (a) may be carried out as follows:

An aqueous polymer dispersion is applied to a mold, which has been preheated, and the water is allowed to evaporate.

Aqueous polymer dispersion can be applied to the mold by conventional methods, especially by spraying, for example with a spray gun.

The mold exhibits patterning, also called structuring, which is produced for example by laser engraving or by molding with a negative mold. The patterning can correspond to the positive or the negative of a fishscale pattern or preferably of a pattern of a sharkskin.

To structure the mold by laser engraving, it is preferable for the laser-engravable layer to be amplified prior to laser engraving by heating (thermochemically), by irradiating with UV light (photochemically) or by irradiating with high-energy radiation (actinically) or any desired combination thereof.

Thereafter, the laser-engravable layer or the layer composite is applied to a cylindrical (temporary) support, for example of plastic, glassfiber-reinforced plastics, metal or foam, for example using adhesive tape, reduced pressure, clamping devices or magnetic force, and engraved as described above. Alternatively, the planar layer or the layer composite can also be engraved as described above. Optionally, the laser-engravable layer is washed during the laser-engraving operation using a rotary cylindrical washer or a continuous washer with a cleaning agent to remove engraving residues.

The mold can be produced in the manner described as a negative mold or as a positive mold.

In a first version, the mold has a negative structure, so that the coating which is bondable to foil (A) is obtainable directly by application of a liquid plastics material to the surface of the mold and subsequent solidification of the polymer.

In a second version, the mold has a positive structure, so that initially a negative mold is produced from the laser-structured positive mold. The coating bondable to a sheetlike support can then be obtained from this negative mold by application of a liquid plastics material to the surface of the negative mold and subsequent solidification of the plastics material.

Preferably, structural elements having dimensions in the range from 10 to 500 μm are engraved into the mold. The structural elements may be in the form of elevations or depressions. Preferably, the structural elements have a simple geometric shape and are for example circles, ellipses, squares, diamonds, triangles and stars. The structural elements may form a regular or irregular grid. Examples are a classic grid of point or a random grid, for example a frequency-modulated grid.

In one embodiment of the present invention, the mold is structured by using a laser to cut wells into the mold which have an average depth in the range from 50 to 250 μm and a center-to-center spacing in the range from 50 to 250 μm.

For example, the mold can be engraved such that it has wells having a diameter in the range from 10 to 500 μm at the surface of the mold. The diameter at the surface of the mold is preferably in the range from 20 to 250 μm and more preferably in the range from 30 to 150 μm. The spacing of the wells can be for example in the range from 10 to 500 μm, preferably in the range from 20 to 200 μm and more preferably up to 80 μm.

In one embodiment of the present invention, the mold preferably has a surficial coarse structure as well as a surficial fine structure. Both the coarse structure and the fine structure can be produced by laser engraving. The fine structure can be for example a microroughness having a roughness amplitude in the range from 1 to 30 μm and a roughness frequency in the range from 0.5 to 30 μm. The dimensions of the microroughness are preferably in the range from 1 to 20 μm, more preferably in the range from 2 to 15 μm and more preferably in the range from 3 to 10 μm.

IR lasers in particular are suitable for laser engraving. However, it is also possible to use lasers having shorter wavelengths, provided the laser is of sufficient intensity. For example, a frequency-doubled (532 nm) or frequency-tripled (355 nm) Nd-YAG laser can be used, or else an Excimer laser (248 nm for example). The laser-engraving operation may utilize for example a CO₂ laser having a wavelength of 10 640 nm. It is particularly preferable to use lasers having a wavelength in the range from 600 to 2000 nm. Nd-YAG lasers (1064 nm), IR diode lasers or solid-state lasers can be used for example. Nd/YAG lasers are particularly preferred. The image information to be engraved is transferred directly from the layout computer system to the laser apparatus. The laser can be operated either continuously or in a pulsed mode.

The mold obtained can generally be used directly as produced. If desired, the mold obtained can additionally be cleaned. Such a cleaning step removes loosened but possibly still not completely detached layer constituents from the surface. In general, simply treating with water, water/surfactant, alcohols or inert organic cleaning agents which are preferably low-swelling will be sufficient.

In a further step, an aqueous formulation of polymer is applied to the mold. The applying may preferably be effected by spraying. The mold should have been heated when the formulation of polymer is applied, for example to temperatures of at least 80° C. and preferably at least 90° C. The water from the aqueous formulation of polymer evaporates and forms the capillaries in the solidifying polymer layer.

Aqueous in connection with the polymer dispersion is to be understood as meaning that the polyurethane dispersion comprises water, but less than 5 wt %, based on the dispersion, preferably less than 1 wt % of organic solvent. It is particularly preferable for there to be no detectable volatile organic solvent. Volatile organic solvents herein are such organic solvents as have a boiling point of up to 200° C. at standard pressure.

The aqueous polymer dispersion can have a solids content in the range from 5 to 60 wt %, preferably in the range from 10 to 50 wt % and more preferably in the range from 25 to 45 wt %.

Suitable polymers include for example polyacrylates, epoxy resins, polyvinyl acetates, polyvinyl chlorides, polyvinylidene chloride, polyacrylonitrile, polystyrenes, polybutadienes, polyurethanes or mixtures thereof.

Polystyrene in the context of the present invention is to be understood as meaning inter alia all homo- or copolymers formed by polymerization of styrene and/or derivatives of styrene. Derivatives of styrene include for example alkylstyrenes such as alpha-methylstyrene, ortho-methylstyrene, meta-methylstyrene, para-methylstyrene, para-butylstyrene especially para-tert-butylstyrene, alkoxystyrene such as para-methoxystyrene, para-butoxystyrene, para-tert-butoxystyrene.

The average molar mass Mₙ of suitable polystyrenes is generally in the range from 5000 to 1 000 000 g/mol (determined by GPC), preferably in the range from 20 000 to 750 000 g/mol and more preferably in the range from 30 000 to 500 000 g/mol.

In one preferred embodiment, the matrix of the color converter consists essentially or completely of a homopolymer of styrene or styrene derivatives.

In further preferred embodiments of the invention, the matrix consists essentially or completely of a styrene copolymer which, for the purposes of this application, is likewise regarded as a polystyrene. Styrene copolymers may comprise for example, as further constituents, butadiene, acrylonitrile, maleic anhydride, vinylcarbazole or esters of acrylic, methacrylic or itaconic acid as monomers. Suitable styrene copolymers generally comprise at least 20 wt % of styrene preferably at least 40 and more preferably at least 60 wt % of styrene. In another embodiment, they comprise at least 90 wt % of styrene. Preferred styrene copolymers are styrene-acrylonitrile copolymers (SAN) and acrylonitrile-butadiene-styrene copolymers (ABS), styrene-1,1′-diphenyl-ethene copolymers, acrylic ester-styrene-acrylonitrile copolymers (ASA), styrene-butadiene copolymers (such as SB dispersions), methyl methacrylate-acrylonitrile-butadiene-styrene copolymers (MABS).

A further preferred polymer is alpha-methylstyrene-acrylonitrile copolymer (AMSAN).

Styrene homo- or copolymers are obtainable for example by free-radical polymerization, cationic polymerization, anionic polymerization or under the influence of organometallic catalysts (Ziegler-Natta catalysis for example). This can lead to isotactic, syndiotactic, atactic polystyrene/copolymers. They are preferably prepared by free-radical polymerization. The polymerization can be carried out as suspension polymerization, emulsion polymerization, solution polymerization or bulk polymerization.

Suitable polyacrylates generally have a molecular weight of 5000 to 1 000 000 g/mol. Suitable polyacrylates are preferably obtainable by free-radical (co)polymerization of appropriate comonomers, preferably by free-radical emulsion copolymerization which, in the context of the present invention, is also simply referred to as free-radical emulsion polymerization. Polyacrylate dispersions are also obtainable via solution copolymerization. The latter is known from U.S. Pat. No. 5,221,284, U.S. Pat. No. 5,376,459 for example.

Particular preference is given to polyacrylates obtainable selected from at least one of the following monomers via free-radical copolymerization:
1) acrylic acid and methacrylic acid and their derivatives of the formula CH₂═CR¹—CO—OR², where R¹ is hydrogen or methyl and R² is a hydrocarbon moiety of 1 to 40 carbon atoms which may also be substituted by fluorine, hydroxyl, C₁₋₄alkylamino, C₁₋₄alkoxy, carbonyl groups and also polyether groups, preferably with R² having 1 to 10 carbon atoms and more preferably with R² being methyl, ethyl, propyl, isopropyl, butyl, tert-butyl, hexyl, ethylhexyl;
2) acrylamide, methyacrylamide and derivatives thereof,
3) styrene and substituted styrenes such as alpha-methylstyrene,
4) acrylonitrile,
5) vinyl esters such as vinyl acetate, vinyl propionate and/or
6) unsaturated dicarboxylic acids such as crotonic acid, haconic acid or maleic anhydride. Suitable binders also include mixtures of polyacrylate and polyurethane dispersions or dispersions obtained by grafting acrylate comonomers onto polyurethane dispersions (PUR-PAC hybrids), with the proviso that they have a Shore A hardness appropriate for production of primers and optionally are self-crosslinking or crosslinkable with customary crosslinkers.
7) olefins such as ethylene.

In one preferred embodiment, suitable polyacrylates comprise no copolymerized comonomers capable of detaching formaldehyde on exposure to temperatures in the range from 100 to 250° C., such as N-methylol(meth)acrylamide for example.

In another embodiment, suitable polyacrylates do comprise copolymerized comonomers capable of detaching formaldehyde on exposure to temperatures in the range from 100 to 250° C., such as N-methylol(meth)acrylamide for example.

Suitable polyacrylates are preferably obtained by free-radical copolymerization of at least two comonomers of which at least one is selected from (meth)acrylic acid and (meth)acrylates, for example C₁-C₂₀-alkyl(meth)acrylates and preferably C₁-C₁₀-alkyl(meth)acrylates, and which preferably account for at least 50 wt % of binder (A).

In one embodiment of the present invention, suitable polyacrylates are selected from copolymers comprising as copolymerized comonomer (meth)acrylic acid, comonomer having an epoxy group in the molecule such as for example glycidyl(meth)acrylate, ω-C₂-C₁₀-hydroxyalkyl (meth)acrylate or (meth)acrylic esters of alcohols of the general formula I

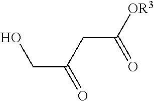

where
R³ is selected from branched and preferably unbranched C₁-C₁₀-alkyl, such as methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl, n-heptyl, n-octyl, 2-ethylhexyl, n-nonyl, n-decyl, more preferably unbranched C₁-C₄-alkyl such as methyl, ethyl, n-propyl and n-butyl.

Useful poly(meth)acrylates for the purposes of the present invention further include copolymers of one or more C₁-C₁₀-alkyl esters of (meth)acrylic acid, which may comprise for example (meth)acrylic acid, glycidyl(meth)acrylate or C₂-C₁₀-hydroxyalkyl(meth)acrylate and optionally one or more further comonomers in copolymerized form. Useful further monomers include for example vinylaromatics such as α-methylstyrene, para-methylstyrene and especially styrene, also (meth)acrylamide, vinyl chloride, (meth)acrylonitrile.

Examples of particularly suitable C₁-C₁₀-alkyl esters of (meth)acrylic acid are methyl (meth)acrylate, ethyl(meth)acrylate, n-propyl(meth)acrylate, isopropyl(meth)acrylate, n-butyl(meth)acrylate, n-hexyl(meth)acrylate, 2-ethylhexyl(meth)acrylate, n-decyl (meth)acrylate.

Examples of particularly suitable ω-hydroxy-C₂-C₁₀-alkylene esters of (meth)acrylic acid are especially ω-hydroxy-C₂-C₁₀-(meth)acrylates such as 6-hydroxyhexyl(meth)acrylate, 4-hydroxybutyl(meth)acrylate, 3-hydroxypropyl(meth)acrylate and especially 2-hydroxyethyl (meth)acrylate.

One preferred version comprises selecting suitable polyacrylates from such poly(meth)acrylates as comprise copolymers of one or more C₁-C₁₀-alkyl esters or (meth)acrylic acid and (meth)acrylic acid and at least one comonomer selected from glycidyl(meth)acrylate and C₂-C₁₀-hydroxyalkyl(meth)acrylate in copolymerized form, plus optionally one or more further comonomers.

When polyacrylates comprising (meth)acrylic acid in copolymerized form are used, the carboxyl groups of the copolymerized (meth)acrylic acid can be present in free form or in completely or partially neutralized form, for example completely or partially neutralized with alkali, with ammonia or with amine. Particularly suitable amines include for example tertiary amines, e.g., (C₁-C₄-alkyl)₃N, especially triethylamine, and alkanolamines such as for example ethanolamine, diethanolamin, triethanolamine, N-methylethanolamine, N,N-dimethylethanolamine and N-(n-butyl)ethanolamine.

Suitable polybutadienes are generally copolymers of butadiene with acrylonitrile and/or styrene and/or (meth)acrylic esters and/or optionally other unsaturated monomers. Suitable polybutadienes dispersions can be crosslinked with metal oxides such as zinc oxide on application.

Suitable polyvinylidene chlorides are generally copolymers of vinylidene chloride with (meth)acrylic esters. Products of this type are marketed for example under the trade name of Diofan®.

Suitable polyvinyl chlorides (PVC) are preferably obtained by homopolymerization of vinyl chloride. In another embodiment, suitable polyvinyl chlorides are obtained by copolymerization of vinyl chloride with other comonomers.

Suitable polyvinyl chlorides are obtainable for example by emulsion polymerization or suspension polymerization.

Suitable polyvinyl chloride dispersions are commercially available for example under the trade names of SolVin® or Diofan®.

Epoxy resins are prepared either by catalytic polymerization of epoxides (oxiranes) or by reaction of epoxides, for example epichlorohydrin with diols, for example with bisphenols such as bisphenol A or bisphenol F.

Suitable epoxy resins can be for example liquid or solid resins based on bisphenol A or F. Suitable liquid epoxy resins, such as bisphenol A diglycidyl ethers, typically have a molecular weight of 200 to 1000 g/mol, preferably of 300 to 500 g/mol and more preferably of about 380 g/mol. Suitable epoxy resins are frequently bifunctional. A molar mass of 380 g/mol then corresponds to an epoxy equivalent weight (EEW) of 190 g/mol. No further additives are needed to use the inexpensive, water-insoluble, liquid resins in aqueous systems. In these cases, the hardener used acts as an emulsifier.

Suitable hydrophobic solid resins frequently have a molecular weight of 500 to 5000 g/mol, preferably of 700 to 3000 g/mol, more preferably of 900 to 2000 g/mol and more preferably of 1000 to 1500 g/mol. In untreated form they are not compatible with waterborne systems. Dispersions of such resins are obtainable by using reactive nonionic emulsifiers. Stable emulsions generally have an average particle diameter of less than one micrometer.

The less preferable solventborne 2-part epoxy resins based on bisphenol A diglycidyl ethers can be hardened with amines and amine derivatives or mercaptans for example. The amine hardeners used for this purpose can be for example cycloaliphatic low molecular weight amines such as meta-xylenediamine (MXDA), isophoronediamine (IPDA), diethylenetriamine (DETA), triethylenetetraamine (TETA), polymeric polyaminoamides or water-soluble emulsifying amine-containing polymers.

Suitable aqueous 2-part epoxy resin systems are obtainable for example by emulsifying liquid epoxy resins with suitable surface-active compounds and modifying hardeners such as polyamidoamine hardeners for example through addition of emulsifiers and protonation to the effect that they became water-soluble.

Aqueous hardeners may consist at the molecular level of a balanced ratio of hydrophobic and hydrophilic elements which permit self-emulsification on the part of liquid resins. The above-mentioned amines can be used for this as a reactant and later crosslinking site because their structure tends to be either hydrophilic (TETA for example) or hydrophobic (IPDA for example). Typical hydrophilic elements of a hardener structure are for example nonionic polyethylene-polypropylene glycol elements of differing molecular weight, while bisphenol A diglycidyl ether compounds are frequently used as hydrophobic component. Hardeners having a variety of properties are obtainable by carefully constructing the molecular structure from these or similar building blocks. Typical self-emulsifying epoxy hardeners are available from BASF under the trade names of WEX, Waterpoxy® for example.

Among aqueous epoxy resin systems there are especially two different types which are suitable, which are known as type I and type II systems. Type I systems are based on liquid resin systems of EEW<250. Type II systems are based on solid resin emulsions of EEW>250.

In type I systems, the hardener used acts not only as hardener but also as emulsifier for the liquid resin. This means that the emulsion particles in such systems comprise not only resin but also hardener very quickly after the mixing of resin and hardener. In addition, a certain proportion of the hardener can also be present in the aqueous phase. The spatial closeness of resin and hardener within the same emulsion particle frequently leads to rapid curing with correspondingly short pot life (<3 h). One advantage of type I systems is that they can often be formulated to be completely VOC-free. Owing to the short spacings of the crosslink points and the rigid polymer backbone, the cured films combine high hardness with an often low flexibility and high chemical resistance.

Type II systems are typically based on solid resin emulsions of EEW>250 and a solids content of 45-62%. Since the solid resin is already in the form of an emulsion, the use of self-emulsifying hardeners as in type I systems is not absolutely necessary, although it is still perfectly possible. Accordingly, a distinctly wider range of useful hardeners is available for type II systems. For example, non-self-emulsifying hardeners such as amine-based hardeners such as Waterpoxy® 801 can be used, but also self-emulsifying hardeners such as Waterpoxy® 751 for example.

Unlike type I systems, the emulsified higher molecular weight solid resins of the type II systems need coalescers in order that good filming may be ensured. Accordingly, unlike type I systems, they usually have a VOC content of 50-150 g/l. It is likewise possible to use VOC-free solid resin emulsions.

Polyurethanes (PUs) are common general knowledge, commercially available and consist in general of a soft phase of comparatively high molecular weight polyhydroxy compounds, for example of polycarbonate, polyester or polyether segments, and a urethane hard phase formed from low molecular weight chain extenders and di- or polyisocyanates.

Polyurethanes (PUs) are common general knowledge, commercially available and consist in general of a soft phase of comparatively high molecular weight polyhydroxy compounds, for example of polycarbonate, polyester or polyether segments, and a urethane hard phase formed from low molecular weight chain extenders and di- or polyisocyanates.

Processes for preparing polyurethanes (PUs) are common general knowledge. In general, polyurethanes (PUs) are prepared by reaction of
(j) isocyanates, preferably diisocyanates, with
(vi) isocyanate-reactive compounds, typically having a molecular weight (Mw) in the range from 500 to 10 000 g/mol, preferably in the range from 500 to 5000 g/mol and more preferably in the range from 800 to 3000 g/mol, and
(vii) chain extenders having a molecular weight in the range from 50 to 499 g/mol, optionally in the presence of
(viii) catalysts
(ix) and/or customary additive materials.

In what follows, the starting components and processes for preparing the preferred polyurethanes (PUs) will be described by way of example. The components (i), (ii), (iii) and also optionally (iv) and/or (v) customarily used in the preparation of polyurethanes (PUs) will now be described by way of example:

As isocyanates (i) there may be used commonly known aliphatic, cycloaliphatic, araliphatic and/or aromatic isocyanates, examples being tri-, tetra-, penta-, hexa-, hepta- and/or octamethylene diisocyanate, 2-methylpentamethylene 1,5-diisocyanate, 2-ethylbutylene 1,4-diisocyanate, pentamethylene 1,5-diisocyanate, butylene 1,4-diisocyanate, 1-isocyanato-3,3,5-trimethyl-5-isocyanatomethylcyclohexane (isophorone diisocyanate, IPDI), 1,4- and/or 1,3-bis(isocyanatomethyl)cyclohexane (HXDI), 1,4-cyclohexane diisocyanate, 1-methyl-2,4- and/or -2,6-cyclohexane diisocyanate and/or 4,4′-, 2,4′- and 2,2′-dicyclohexylmethane diisocyanate, 2,2′-, 2,4′- and/or 4,4′-diphenylmethane diisocyanate (MDI), 1,5-naphthylene diisocyanate (NDI), 2,4- and/or 2,6-toluoylene diisocyanate (TDI), diphenylmethane diisocyanate, 3,3′-dimethylbiphenyl diisocyanate, 1,2-diphenylethane diisocyanate and/or phenylene diisocyanate. Preference is given to using 4,4′-MDI. Preference is also given to aliphatic diisocyanates, especially hexamethylene diisocyanate (HDI), and particular preference is given to aromatic diisocyanates such as 2,2′-, 2,4′- and/or 4,4′-diphenylmethane diisocyanate (MDI) and mixtures of the aforementioned isomers.

As isocyanate-reactive compounds (ii) there may be used the commonly known isocyanate-reactive compounds, examples being polyesterols, polyetherols, and/or polycarbonate diols, which are customarily also subsumed under the term “polyols”, with molecular weights (M_{w}) in the range from 500 to 8000 g/mol, preferably in the range from 600 to 6000 g/mol and especially in the range from 800 to 3000 g/mol, and preferably with an average functionality toward isocyanates in the range from 1.8 to 2.3, preferably in the range from 1.9 to 2.2 and especially 2. Preference is given to using polyether polyols, for example those based on commonly known starter substances and customary alkylene oxides, for example ethylene oxide, 1,2-propylene oxide and/or 1,2-butylene oxide, preferably polyetherols based on polyoxytetramethylene (polyTHF), 1,2-propylene oxide and ethylene oxide. Polyetherols have the advantage of having a higher hydrolysis stability than polyesterols, and are preferably used as component (ii), especially for preparing soft polyurethanes polyurethane (PU1).

As polycarbonate diols there may be mentioned in particular aliphatic polycarbonate diols, for example 1,4-butanediol polycarbonate and 1,6-hexanediol polycarbonate.

As polyester diols there are to be mentioned those obtainable by polycondensation of at least one primary diol, preferably at least one primary aliphatic diol, for example ethylene glycol, 1,4-butanediol, 1,6-hexanediol, neopentylglycol or more preferably 1,4-dihydroxymethylcyclohexane (as isomer mixture) or mixtures of at least two of the aforementioned diols on the one hand and at least one, preferably at least two dicarboxylic acids or their anhydrides on the other. Preferred dicarboxylic acids are aliphatic dicarboxylic acids such as adipic acid, glutaric acid, succinic acid and aromatic dicarboxylic acids such as, for example, phthalic acid and especially isophthalic acid.

Polyetherols are preferably prepared by addition of alkylene oxides, especially ethylene oxide, propylene oxide and mixtures thereof, on to diols such as, for example, ethylene glycol, 1,2-propylene glycol, 1,2-butylene glycol, 1,4-butanediol, 1,3-propanediol, or on to triols such as, for example, glycerol, in the presence of high-activity catalysts. High-activity catalysts of this type are for example cesium hydroxide and dimetal cyanide catalyst, also known as DMC catalysts. Zinc hexacyanocobaltate is a frequently employed DMC catalyst. The DMC catalyst can be left in the polyetherol after the reaction, but preferably it is removed, for example by sedimentation or filtration.

Mixtures of various polyols can be used instead of just one polyol.

To improve dispersibility, isocyanate-reactive compounds (ii) may also include a proportion of one or more diols or diamines having a carboxylic acid group or sulfonic acid group (b′), especially alkali metal or ammonium salts of 1,1-dimethylolbutanoic acid, 1,1-dimethylolpropionic acid or

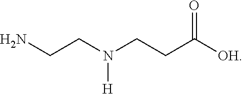

Useful chain extenders (iii) include commonly known aliphatic, araliphatic, aromatic and/or cycloaliphatic compounds having a molecular weight in the range from 50 to 499 g/mol and at least two functional groups, preferably compounds having exactly two functional groups per molecule, examples being diamines and/or alkanediols having 2 to 10 carbon atoms in the alkylene moiety, especially 1,3-propanediol, 1,4-butanediol, 1,6-hexanediol and/or di-, tri-, tetra-, penta-, hexa-, hepta-, octa-, nona- and/or decaalkylene glycols having 3 to 8 carbon atoms per molecule, preferably the corresponding oligo- and/or polypropylene glycols, and mixtures of chain extenders (iii) can also be used.

It is particularly preferable for components (i) to (iii) to be difunctional compounds, i.e., diisocyanates (i), difunctional polyols, preferably polyetherols (ii) and difunctional chain extenders, preferably diols.

Useful catalysts (iv), which speed especially the reaction between the NCO groups of the diisocyanates (i) and the hydroxyl groups of components (ii) and (iii), are customary tertiary amines, for example triethylamine, dimethylcyclohexylamine, N-methylmorpholine, N,N′-dimethylpiperazine, 2-(dimethylaminoethoxy)ethanol, diazabicyclo(2,2,2)octane (DABCO) and similar tertiary amines, and also especially organic metal compounds such as titanic esters, iron compounds such as, for example, iron(III) acetylacetonate, tin compounds, for example tin diacetate, tin dioctoate, tin dilaurate or the tin dialkyl salts of aliphatic carboxylic acids such as dibutyltin diacetate, dibutyltin dilaurate or the like. The catalysts are typically used in amounts of 0.0001 to 0.1 part by weight per 100 parts by weight of component (ii).

Auxiliaries and/or additives (v) can be added to the components (i) to (iii) as well as catalyst (iv). There may be mentioned for example blowing agents, antiblocking agents, surface-active substances, fillers, for example fillers based on nanoparticles, especially fillers based on CaCO₃, nucleators, glidants, dyes and pigments, antioxidants, for example against hydrolysis, light, heat or discoloration, organic and/or inorganic fillers, reinforcing agents and plasticizers, metal deactivators. In one preferred embodiment, component (v) also includes hydrolysis stabilizers such as, for example polymeric and low molecular weight carbodiimides. The soft polyurethane preferably comprises triazole and/or triazole derivative and antioxidants in an amount of 0.1 to 5 wt % based on the total weight of the soft polyurethane in question. Useful antioxidants are generally substances that inhibit or prevent unwanted oxidative processes in the plastics material to be protected. In general, antioxidants are commercially available. Examples of antioxidants are sterically hindered phenols, aromatic amines, thiosynergists, organophosphorous compounds of trivalent phosphorous and hindered amine light stabilizers. Examples of sterically hindered phenols appear in the Plastics Additive Handbook, 5th edition, H. Zweifel, ed, Hanser Publishers, Munich, 2001 ([1]), pp. 98-107 and p. 116-p. 121. Examples of aromatic amines appear in [1] pp. 107-108. Examples of thiosynergists are given in [1], pp. 104-105 and pp. 112-113. Examples of phosphites are given in [1], pp. 109-112. Examples of hindered amine light stabilizers are given in [1], pp. 123-136. Phenolic antioxidants are preferable for use in the antioxidant mixture. In one preferred embodiment, the antioxidants, especially phenolic antioxidants, have a molar mass of above 350 g/mol and more preferably of above 700 g/mol and a maximum molar mass (M_{w}) of not more than 10 000 g/mol and preferably up to not more than 3000 g/mol. They further preferably have a melting point of not more than 180° C. It is further preferable to use antioxidants that are amorphous or liquid. Mixtures of two or more antioxidants can likewise be used as component (v).

As well as the recited components (i), (ii) and (iii) and optionally (iv) and (v), chain transfer agents (chain-terminating agents), customarily having a molecular weight of 31 to 3000 g/mol, can also be used. Such chain transfer agents are compounds which have only one isocyanate-reactive functional group, examples being monofunctional alcohols, monofunctional amines and/or monofunctional polyols. Such chain transfer agents make it possible to adjust flow behavior, especially in the case of soft polyurethanes, to specific values. Chain transfer agents can generally be used in an amount of 0 to 5 parts and preferably 0.1 to 1 part by weight, based on 100 parts by weight of component (ii), and by definition come within component (iii).

As well as the recited components (i), (ii) and (iii) and optionally (iv) and (v), it is also possible to use crosslinkers having two or more isocyanate-reactive groups at the end of the polyurethane-forming reaction, for example hydrazine hydrate.

To adjust the hardness of polyurethane (PU), the components (ii) and (iii) can be chosen within relatively wide molar ratios. Useful are molar ratios of component (ii) to total chain extenders (iii) to be used in the range from 10:1 to 1:10 and especially in the range from 1:1 to 1:4, the hardness of soft polyurethanes increasing with increasing (iii) content. The reaction to produce polyurethane (PU) can be carried out at an index in the range from 0.8 to 1.4:1, preferably in the range from 0.9 to 1.2:1 and more preferably at an index in the range from 1.05 to 1.2:1. The index is defined by the ratio of all the isocyanate groups of component (i) to the isocyanate-reactive groups, i.e., the active hydrogens, of components (ii) and optionally (iii) and optionally monofunctional isocyanate-reactive components as chain-terminating agents such as monoalcohols for example.

Polyurethane (PU) can be prepared by conventional processes in a continuous manner, for example by the one-shot or the prepolymer process, or batchwise by the conventional prepolymer operation. In these processes, the reactant components (i), (ii), (iii) and optionally (iv) and/or (v) can be mixed in succession or simultaneously, and the reaction ensues immediately.

Polyurethane (PU) can be dispersed in water in a conventional manner, for example by dissolving polyurethane (PU) in acetone or preparing it as a solution in acetone, and mixing the solution with water and then removing the acetone, for example distillatively. In one version, polyurethane (PU) is prepared as a solution in N-methylpyrrolidone or N-ethylpyrrolidone, admixed with water and the N-methylpyrrolidone or N-ethylpyrrolidone is removed.

In one embodiment of the present invention, aqueous dispersions of the present invention comprise two different polyurethanes polyurethane (PU1) and polyurethane (PU2), of which polyurethane (PU1) is a so-called soft polyurethane which is constructed as described above for polyurethane (PU), and at least one hard polyurethane (PU2).

Hard polyurethane (PU2) can in principle be prepared similarly to soft polyurethane (PU1), but other isocyanate-reactive compounds (ii) or other mixtures of isocyanate-reactive compounds (ii), herein also referred to as isocyanate-reactive compounds (ii-2) or in short compound (ii-2), are used.

Examples of compounds (ii-2) are in particular 1,4-butanediol, 1,6-hexanediol and neopentylglycol, either mixed with each other or mixed with polyethylene glycol.

In one version of the present invention, diisocyanate (i) and polyurethane (PU2) are each mixtures of diisocyanates, for example mixtures of HDI and IPDI, larger proportions of IPDI being chosen for the preparation of hard polyurethane (PU2) than for the preparation of soft polyurethane (PU1).

In one embodiment of the present invention, polyurethane (PU2) has a Shore A hardness in the range from above 60 to not more than 100, the Shore A hardness being determined in accordance with German standard specification DIN 53505 after 3 s.

In one embodiment of the present invention, polyurethane (PU) has an average particle diameter in the range from 100 to 300 nm and preferably in the range from 120 to 150 nm, determined by laser light scattering.

In one embodiment of the present invention, soft polyurethane (PU1) has an average particle diameter in the range from 100 to 300 nm and preferably in the range from 120 to 150 nm, determined by laser light scattering.

In one embodiment of the present invention, polyurethane (PU2) has an average particle diameter in the range from 100 to 300 nm and preferably in the range from 120 to 150 nm, determined by laser light scattering.

The aqueous polymer dispersion may further comprise at least one curative, which may also be referred to as a crosslinker. Compounds are useful as a curative when they are capable of crosslinking a plurality of polymer molecules together, for example on thermal activation. Suitable crosslinkers are for example polyisocyanates, carbodiimides, dicarbamates, polyaziridines or metal salts such as zinc salts.

Suitable aziridine crosslinkers are described in DE 10256494 for example.

Suitable carbodiimides can have for example the formula

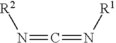

Where R¹ and R² may be the same or different and are each selected from
C₁-C₂₀-alkyl, such as methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl, n-heptyl, n-octyl, 2-ethylhexyl, n-nonyl, n-decyl, n-dodecyl, isododecyl, n-tetradecyl, n-hexadecyl, n-octadecyl, n-eicosyl; preferably C₁-C₁₀-alkyl, such as methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl, n-heptyl, n-octyl, 2-ethylhexyl, n-nonyl, n-decyl, more preferably C₁-C₄-alkyl such as methyl, ethyl, n-propyl, isopropyl, n-butyl, isobutyl, sec-butyl and tert-butyl;
C₃-C₂₀-cycloalkyl, monocyclic or bicyclic, unsubstituted or substituted with for example C₁-C₆-alkyl or with isocyanate, such as cyclopropyl, cyclobutyl, cyclopentyl, cyclohexyl, cycloheptyl, cyclooctyl, 2,5-dimethylcyclopentyl, 2,6-dimethylcyclohexyl, methyl-C₅-C₇-cycloalkyl, isocyanatocyclohexyl, methyl[isocyanato-C₅-C₇-cycloalkyl],
C₆-C₁₄-aryl, unsubstituted or substituted one or more times with for example C₁-C₆-alkyl or with isocyanate or with isocyanato-C₁-C₆-alkyl, especially with C(CH₃)₂—NCO, for example —C₆H₃(CH₃)NCO, —C₆H₄—NCO, C₇-C₁₅-alkylaryl, especially —C(CH₃)₂—C₆H₄—C(CH₃)₂—NCO, meta or para, methyl-C₅-C₇-cycloalkyl, unsubstituted or substituted with isocyanate or with isocyanato-C₁-C₆-alkyl, especially with C(CH₃)₂—NCO,
isophoryl, cyclohexyl,
C₃-C₆-heteryl, for example imidazolyl.

In one embodiment, carbodiimide (C) is a polymeric carbodiimide. Polymeric carbodiimides for the purposes of the present invention are compounds having from 2 to 50 and preferably up to 20 —N═C═N— groups per mole.

Preferred crosslinkers are for example polyisocyanates, especially aliphatic polyisocyanates, for example isocyanurates, biurets, allophanates or uretdiones based on hexamethylene diisocyanate and/or isophorone diisocyanate. Particularly preferred polyisocyanates comprise a hydrophilic group which makes the polyisocyanates easier to disperse in aqueous systems. Particularly preferred polyisocyanates comprise a hydrophilic group which is either anionic or at least one polyether group which is constructed of ethylene oxide at least in part.

In one embodiment of the present invention, aqueous polymer dispersion comprises at least one addition selected from pigments, delusterants, photoprotectants, flame retardants, antioxidants, antistats, antisoil, anticreak, thickening agents, especially thickening agents based on polyurethanes, and hollow microspheres.

In one embodiment of the present invention, aqueous polymer dispersion comprises altogether up to 20 wt % of additions.

Aqueous polymer dispersion may also comprise one or more organic solvents. Suitable organic solvents are for example alcohols such as ethanol or isopropanol and especially glycols, diglycols, triglycols or tetraglycols and doubly or preferably singly C₁-C₄-alkyl-etherified glycols, diglycols, triglycols or tetraglycols. Examples of suitable organic solvents are ethylene glycol, propylene glycol, butylene glycol, diethylene glycol, triethylene glycol, tetraethylene glycol, dipropylene glycol, 1,2-dimethoxyethane, methyltriethylene glycol (methyltriglycol) and triethylene glycol n-butyl ether (butyltriglycol).

After polymer layer (E) has cured, it is separated from the mold, for example by peeling off, to obtain a polymer film which forms the polymer layer (E) in inventive multilayered composite system.

In one embodiment of the present invention, the mold can also be left to serve as a protective layer and only be removed after production of the actual multilayered composite system.

In one version of the inventive production process, step (a) is followed by a step (b). Step (b) comprises applying at least one organic adhesive uniformly or partially to foam layer (C) and/or to polymer layer (E) and then bonding polymer layer (E) to foam layer (C) pointwise, stripwise or areawise.

Thereafter, step (c) comprises optionally bonding the resulting composite body to sheetlike substrate (A) using an organic adhesive, which may be the same as or different from that of step (b).

The adhesive or adhesives is or are cured, for example thermally, by actinic radiation or by aging, to obtain inventive multilayered composite system.

In one other version of the inventive production process, step (a) is followed by a step (b′). It comprises applying at least one organic adhesive uniformly or partially to foam layer (C) and/or to sheetlike substrate (A) and then bonding sheetlike substrate (A) to foam layer (C) pointwise, stripwise or areawise.

Thereafter, step (c′) comprises optionally bonding the resulting composite body to polymer layer (E) using an organic adhesive, which may be the same as or different from that of step (b).

To improve the adherence of polymer layer (E) to the other constituent parts of the inventive multilayered composite system, a compressing operation may be carried out using a calender for example. Suitable molding pressures can be in the range from 1 to 20 bar. Suitable molding times can be in the range from 10 to 200 seconds. Suitable molding temperatures can be in the range from 80 to 140° C.

In one embodiment of the present invention, at least one biocide is applied with organic adhesive in step (b) and/or (c)/(b′) and/or (c′)/(b″) and/or (c″). This can be accomplished for example by incorporating the biocide(s) into adhesive dispersion or aqueous dispersion for producing polymer layer (E), for example by stirring pulverulent or dispersed biocide thereinto before the corresponding precursors.

In one embodiment of the present invention, biocide is an encapsulated biocide. In one other embodiment of the present invention, biocide is not encapsulated.

In one other embodiment of the present invention, biocide is introduced into foam layer (C), for example by drenching foam layer (C) with a preferably aqueous or alcoholic solution or dispersion of biocide and thereafter removing the solvent, for example by evaporating.

In one embodiment of the present invention, one or more electroconductivity-conferring elements are introduced into inventive multilayered composite system.

Electroconductivity-conferring elements may be selected for example from integrated circuits, metallic threads, metallic foils, metallized polymeric foils, sievelike or latticelike metallic braids.

In one version, one or more electroconductivity-conferring elements can be applied to sheetlike substrate (A). In one other version, one or more electroconductivity-conferring elements can be applied to or introduced into the bonding layer (B) or (D), so inventive multilayered composite system includes a bonding layer (B) or (D). In one other version, one or more electroconductivity-conferring elements can be applied to or introduced into foam layer (C). In one other version, one or more electroconductivity-conferring elements can be applied to polymer layer (E).

In one embodiment of the present invention, foam layer (C), sheetlike substrate (A) or preferably polymer layer (E) is printed with at least one integrated circuit before step (b)/(b′)/(b″).

Preferably, one or more electrically conductive elements are placed between polymer layer (E) and bonding layer (D).

We claim:

1. A multilayered composite system comprising
(A) a sheetlike substrate,
(B) optionally a bonding layer, which may be formed uniformly or partially,
(C) a foam layer,
(D) optionally a bonding layer of the same material as said bonding layer (B) or of a material other than said bonding layer (B),
(E) a polymer layer which includes capillaries extending through the entire thickness of said polymer layer (E),
wherein said polymer layer (E) includes a pattern with a fishscale or sharkskin appearance.

2. The multilayered composite system according to claim 1 wherein at least one of said layers (B) to (E) comprises at least one biocide.

3. The multilayered composite system according to claim 1 or 2 wherein said sheetlike substrate (A) is selected from wovens, nonwovens, metallic foils and polymeric foils.

4. The multilayered composite system according to any one of claims 1 to 3 wherein said bonding layer (B) or said bonding layer (D) is a layer of a cured organic adhesive.

5. The multilayered composite system according to any one of claims 1 to 4 wherein said bonding layer (B) is an interrupted layer of a cured organic adhesive.

6. The multilayered composite system according to any one of claims 1 to 5 additionally including electroconductivity-conferring elements (F).

7. The multilayered composite system according to claim 6 wherein said electroconductivity-conferring elements (F) are selected from printed integrated circuits, metallic threads and a metallization.

8. The multilayered composite system according to any one of claims 2 to 7 wherein biocide is encapsulated.

9. The multilayered composite system according to any one of claims 1 to 8 wherein said polymer layer (E) consists essentially of polyacrylate, epoxy resin, polyvinyl acetate, polyvinyl chloride, polyvinylidene chloride, polyacrylonitrile, polystyrene, polybutadienes, polyurethane or mixtures thereof.

10. A process for producing multilayered composite systems which includes the following steps:
(a) using a mold to form a polymer layer (E),
(b) applying at least one organic adhesive uniformly or partially to foam layer (C) and/or to polymer layer (E) and then bonding polymer layer (E) to foam layer (C) pointwise, stripwise or areawise,
(c) optionally bonding the resulting composite body to sheetlike substrate (A) using an organic adhesive.

11. A process for producing multilayered composite systems which includes the following steps:
(a) using a mold to form a polymer layer (E),
(b′) applying at least one organic adhesive uniformly or partially to foam layer (C) and/or to sheetlike substrate (A) and then bonding sheetlike substrate (A) to foam layer (C) pointwise, stripwise or areawise,
(c′) optionally bonding the resulting composite body to polymer layer (E) using an organic adhesive.

12. A process for producing multilayered composite systems which includes the following steps:
(a) using a mold to form a polymer layer (E),
(b″) applying at least one organic adhesive based on a foamable polyurethane in a uniform, pointwise or stripwise manner to polymer layer (E) and/or to a sheetlike substrate (A),
(c″) mutually contacting polymer layer (E) and sheetlike substrate (A) such that the layer of adhesive based on foamable polyurethane comes to be positioned between said polymer layer (E) and said sheetlike substrate (A), and
(d″) foaming the adhesive based on foamable polyurethane to form the foam layer (C).

13. The process according to claim 10, 11 or 12 wherein said polymer layer (E) is produced using a silicone mold.

14. The process according to at least one of claims 10 to 13 wherein a biocide is applied with organic adhesive in step (b) and/or (c)/(b′) and/or (c′)/(b″) and/or (c″).

15. The process according to at least one of claims 10 to 14 wherein polymer layer (E), foam layer (C) and/or sheetlike substrate (A) is/are printed with at least one integrated circuit before performance of step (b)/(b′)/(b″).

16. The use of multilayered composite bodies according to any one of claims 1 to 9 for equipping watercraft and at least partially water-covered facilities.

17. Watercraft equipped with at least one multilayered composite system according to any one of claims 1 to 9.

18. An at least partially water-covered facility equipped with at least one multilayered composite system according to any one of claims 1 to 9.
